(19) United States
(12) Patent Application Publication
(10) Pub. No.: US 2025/0189476 A1
(43) Pub. Date: Jun. 12, 2025

(54) CONTACTING-TYPE CONDUCTIVITY SENSOR WITH CORROSION DIAGNOSTIC

(71) Applicant: Rosemount Inc., Shakopee, MN (US)

(72) Inventors: Charu L. PANDEY, Shakopee, MN (US); Zachary D. BLUM, Minneapolis, MN (US); Trevor J. RUE, Shakopee, MN (US); Keith J. LEWBART, Mount Laurel, NJ (US)

(21) Appl. No.: 18/533,479

(22) Filed: Dec. 8, 2023

(51) Int. Cl. G01N 27/30

(52) U.S. Cl. CPC G01N 27/30

(57) ABSTRACT

A contacting-type conductivity sensor is provided. The sensor includes a first electrode configured to contact a liquid and a second electrode configured to contact the liquid. The second electrode has a first end and a second end. A first conductor is coupled to the first electrode, a second conductor coupled to the first end of the second electrode, and a third conductor coupled to the second end of the second electrode. The contacting-type conductivity sensor is configured to provide a conductivity measurement of liquid using the first and second conductor and is configured to provide a corrosion diagnostic using the second conductor and the third conductor. A conductivity measurement system using the sensor is provided along with a method of using the sensor.

### BACKGROUND

Liquid conductivity measurement systems are used for the measurement of conductivity of water and aqueous or non-aqueous solutions in environmental, medical, industrial, and other applications where an indication of the ionic content of the liquid is required.

Liquid conductivity is measured in a variety of contexts to provide a relatively inexpensive parameter that can be sometimes related to bulk ionic concentration. In situations where a single type of ion is present, the conductivity can actually be related to specific ionic concentration. Even in situations where a number of different ionic compounds are present, the measurement of bulk liquid conductivity can still provide very useful information. Accordingly, there has been widespread adoption and utilization of conductivity measurement by the industry for a variety of different purposes.

Typically, contact-based conductivity measurement systems include a conductivity sensor or cell and an associated conductivity analyzer or meter. A conductivity meter generates an AC current through electrodes of the conductivity cell. The meter then senses the resultant voltage between the electrodes of the cell. This voltage is generally a function of the conductivity of the liquid to which the cell is exposed.

### SUMMARY

A contacting-type conductivity sensor is provided. The sensor includes a first electrode configured to contact a liquid and a second electrode configured to contact the liquid. The second electrode has a first end and a second end. A first conductor is coupled to the first electrode, a second conductor coupled to the first end of the second electrode, and a third conductor coupled to the second end of the second electrode. The contacting-type conductivity sensor is configured to provide a conductivity measurement of liquid using the first and second conductor and is configured to provide a corrosion diagnostic using the second conductor and the third conductor. A conductivity measurement system using the sensor is provided along with a method of using the sensor.

### BRIEF DESCRIPTION OF THE DRAWINGS

FIG. 1 illustrates a typical contacting-type conductivity sensor and an associated conductivity analyzer or meter.

FIG. 2A is a diagrammatic perspective view of a typical contacting-type conductivity sensor.

FIG. 2B is an enlarged diagrammatic view of a portion of the contacting-type conductivity sensor shown in FIG. 2A.

FIG. 3 is a diagrammatic view of a simple cooling water system.

FIGS. 4A and 4B are diagrammatic top and perspective views of a contacting-type conductivity sensor in accordance with an embodiment of the present invention.

FIG. 5 is a circuit diagram illustrating for measurement of corrosion of an electrode of a contacting-type conductivity sensor in accordance with an embodiment of the present invention.

FIG. 6 is a flow diagram of a method of measuring corrosion of a contacting-type conductivity sensor in accordance with an embodiment of the present invention.

### DETAILED DESCRIPTION

Contacting-type conductivity sensors are widely employed in industries for determining the concentration of ions in solution. Some ions, like hydrogen and chloride, are very corrosive to metal components, such as pipes, heat exchangers, and other equipment. While pH probes are employed to measure hydrogen ion concentration in solution, conductivity probes do not provide information on the types of ions in the mix. It is a measurement of the overall concentration of ions. Moreover, even if the pH of a solution were between 6 and 9, processes like seawater processing can still be corrosive, owing to the high concentration of other ions. The concentration of total ions in solution is known as conductivity.

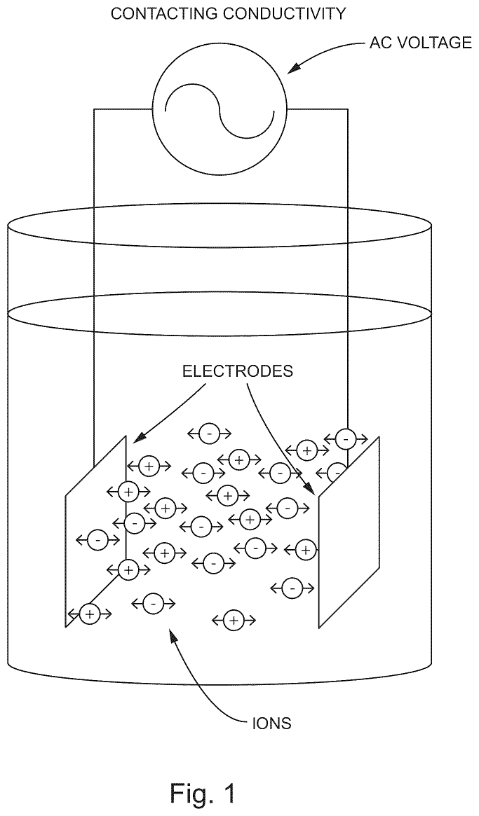

FIG. 1 illustrates a typical contacting-type conductivity sensor and an associated conductivity analyzer or meter. A conductivity meter generates an AC voltage across electrodes of the conductivity cell. The conductivity meter then senses the resultant current between the electrodes of the cell. This current is generally a function of the conductivity of the liquid to which the cell is exposed. The current between the electrodes depends not only on the solution conductivity, but also on the length, surface area, and geometry of the sensor electrodes. The probe constant (also called sensor constant or cell constant) is a measure of the response of a sensor to a conductive solution, due to the sensor's dimensions and geometry. Its units are cm-1 (length divided by area), and the probe constant necessary for a given conductivity range is based on the particular conductivity analyzer's measuring circuitry. Probe constants can vary from 0.01 cm-1 to 50 cm-1 and, in general, the higher the conductivity, the larger the probe constant necessary.

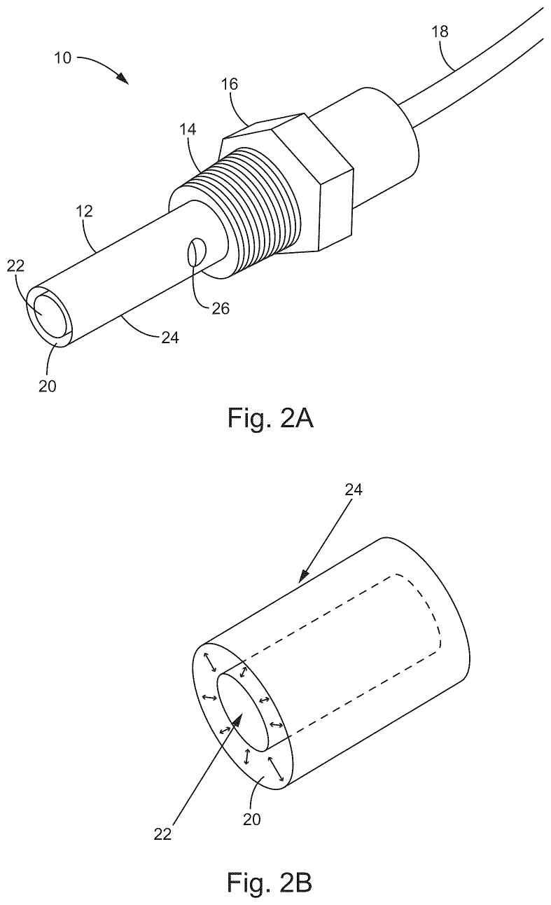

FIG. 2A is a diagrammatic perspective view of a typical contacting-type conductivity sensor and FIG. 2B is an enlarged diagrammatic view of a portion of the contacting-type conductivity sensor shown in FIG. 2A. As shown in FIG. 2A, contacting-type conductivity sensor 10 generally includes a distal portion 12 that is configured to be exposed to process liquid. Typically, sensor 10 is mounted to a process by having distal portion 12 extend through a process intrusion with external threads 14 engaging internal threads of the process intrusion. Hex flats 16 are provided to allow a user to employ a wrench to tighten sensor 10 into the process intrusion. A sensor body 18 may include one or more electrical components, such as circuitry as well as suitable electrical connections between the sensor 10 and multiconductor cable 18, which connects to an analyzer (not shown in FIG. 2A).

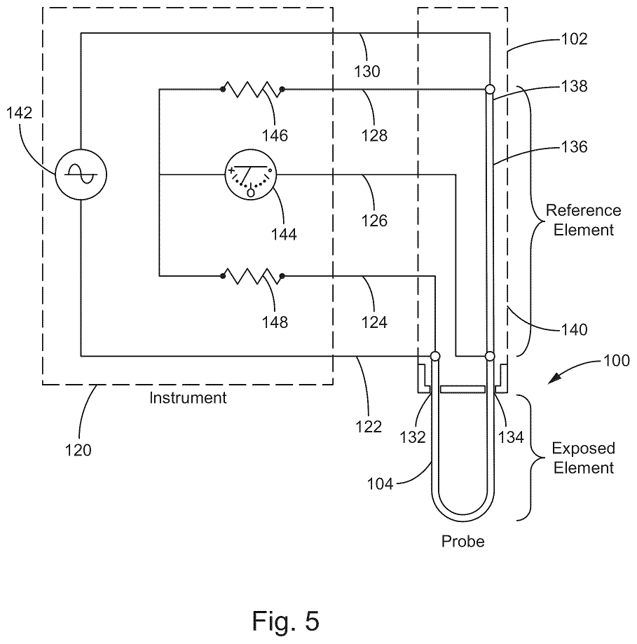

Distal portion 12 of sensor 10 includes an end having annular space 20 between inner electrode 22 and outer electrode 24. Annular space 20 between electrodes 22, 24 is filled with process solution, which exits weep holes 26 on the side of distal portion 12. An analyzer (such as analyzer 120 shown in FIG. 5) applies an AC voltage between inner electrode 22 and outer electrode 24, and as a result the ions in solution move back and forth between the two electrodes 22, 24, forming an ionic current. The sensor or the analyzer then measures the ionic current. From Ohm's law (V=IR), the analyzer calculates a resistance of the solution and obtains the reciprocal of the resistance.

As set forth above, contacting-type conductivity sensors measure the resistance of the solution, which resistance is converted into a conductance and multiplied by the cell constant to yield conductivity. The cell constant is determined by calibration of the sensor against a standard solution or a solution having a known conductivity. The theoretical definition of the cell constant is the distance between the inner and outer electrode divided by the inner surface area of the electrode. Commercially-available contacting-type conductivity sensors are available having various cell constants: 0.01/cm cell constant sensors are made for high purity water applications with conductivities less than 10 μS/cm like boiler feedwater; 0.1/cm cell constant made for cleaner water applications such as cooling water and potable water; and 1.0/cm cell constant made for dirtier processes such as wastewater processing. Sensors with these various constants are available from Emerson Electric Co. of St. Louis, MO. In some instances, these sensors may be factory-calibrated for a more accurate cell constant than the nominal value. Then, end users may simply enter the calibrated cell constant into the user's analyzer and begin taking conductivity measurements. Over time, however, the cell constant can shift, either due to buildup of debris, coating on the electrode(s), or gradual corrosion of the electrodes by the process. Embodiments described below generally provide a contacting-type conductivity sensor with real-time or substantially real-time corrosion diagnostics. It is believed that embodiments described herein will be particularly beneficial for applications such as cooling water and boiler blowdown systems. An added benefit of such diagnostics is corrosion monitoring of pipes and equipment for asset integrity.

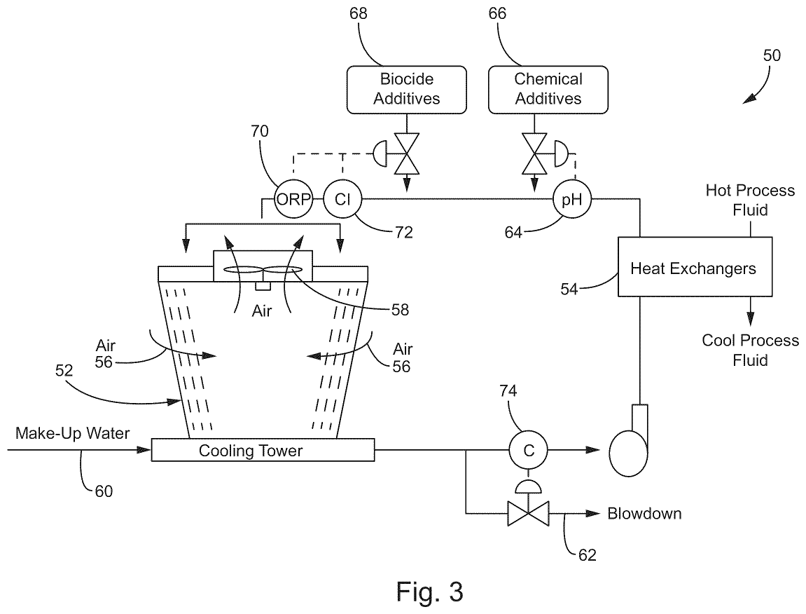

FIG. 3 is a diagrammatic view of a simple cooling water system. System 50 is an example of a cooling water system that is used in a wide range of industries, from power plants to oil refineries, for expelling large quantities of process heat. Cooling tower(s) 52 store large quantities of cooled or chilled water, which is eventually sent to one or more heat exchangers 54 throughout the site. The cooling water absorbs excess heat from the process before leaving heat exchanger(s) 54 and returning to cooling tower(s) 52. As shown in FIG. 3, when the heated water (i.e., water that has passed through a heat exchanger 54) enters the cooling tower 52, it interacts with air 56 to cool. In order to facilitate cooling, air 56 is moved through the cooling tower(s) 52 by fan 58. Make-up water 60 from the city or local reservoirs is used to replenish water lost during blowdown. Blowdown is a process in which cooling water is ejected, as indicated at reference numeral 62, from the system to decrease the conductivity. Corrosion diagnostics are important in cooling water systems. Heat exchangers that foul due to corrosion can prevent optimal heat transfer between the process and cooling water, affecting process quality. Further, equipment failures within a cooling tower can be costly to fix and lead to unplanned shutdowns.

Several substances can cause corrosion in cooling water systems. Leaks through tubes or shells of heat exchangers can lead to pronounced changes in the pH of the cooling water. As shown in FIG. 3, a pH probe 64 is typically installed downstream of heat exchanger(s) 54 to monitor for leaks. Next, microbial induced corrosion can occur from bacteria and algae, as make-up water is continuously supplied from city water or other reservoirs. Chemical additives 66 (such as Free Chlorine) and/or biocide additives 68 are injected into the water to control biological contamination. These additives 66, 68 are monitored with suitable sensors, such as oxidation-reduction potential (ORP) sensor 70 and/or chlorine sensor 72. However, some corrosion can still occur due to the presence of high concentrations of salts such as sodium chloride from leaks in the shell and/or tubes of heat exchangers(s) 54 or failing ion-exchange resins. Installing a contacting-type conductivity sensor, such as conductivity sensor 74, in such applications is very important for determining changes in the conductivity of cooling water. Additionally, in boiler feedwater systems, an oxygen probe is installed after the deaerator to control oxygen concentration that may have entered through gasket leaks in fans and/or pumps.

Typically, metallic corrosion coupons are used in cooling water systems to monitor corrosion rate. Corrosion coupons are pre-weighed pieces of metal installed in bypass racks. Periodically (such as every 3 or 4 months), the coupons are removed from the bypass racks and weighed. The difference in weight from the previous inspection is the corrosion rate, which is typically expressed in terms of mils per year. Corrosion coupons on bypass racks are generally the least expensive corrosion monitoring technology. However, such approaches do not provide a continuous, live measurement for operators. Additionally, many sites may experiment with corrosion inhibitors and corrosion probes are used to conduct experiments with type and dosage of corrosion inhibitors. Again, live measurements can prove more accurate and convenient than using corrosion coupons.

Corrosion of electrodes in contacting-type conductivity sensors will also occur over time in the applications described above. Corrosion of the electrodes decreases the surface area of the annular space between the inner and outer electrodes. This will lead to false readings in the conductivity. A calibration may be performed to adjust the cell constant and can bring the readings back into tolerance. However, users sometimes choose to install contacting-type conductivity sensors in pipes directly, as panel mounts drain valuable cooling water to atmosphere. Additionally, unplanned shutdowns are more difficult to manage and users may not possess a backup sensor. Accordingly, providing a contacting-type conductivity sensor with a live, continuous, or substantially real-time corrosion diagnostic will benefit users of such sensors, and in particular will be of significant value to cooling water applications. The sensor diagnostic can also be used as a predictive tool for maintenance and planned shutdowns, as corrosion measured by the conductivity sensor may be indicative of overall corrosion in the cooling system.

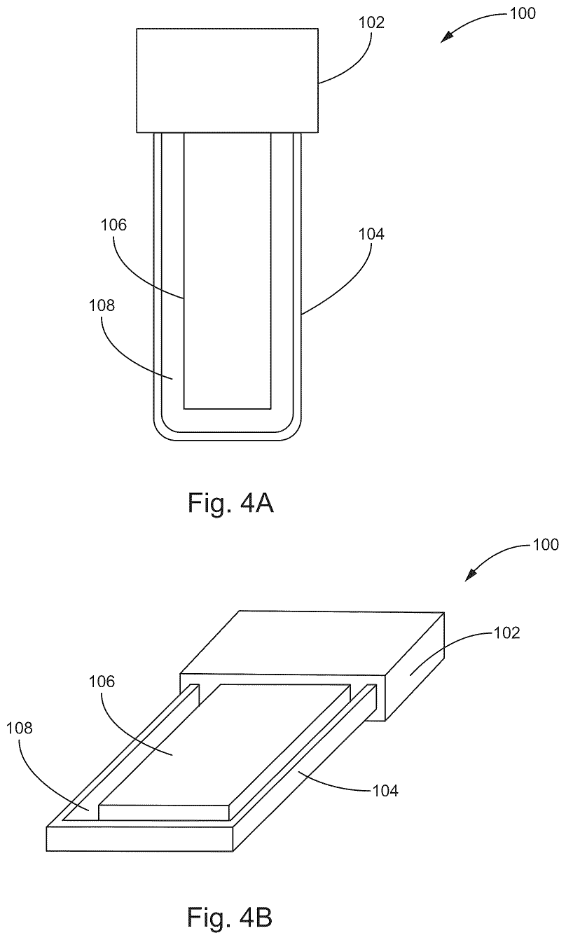

FIGS. 4A and 4B are diagrammatic top and perspective views of a contacting-type conductivity sensor in accordance with an embodiment of the present invention. Sensor 100 includes sensor body 102, a portion of which is shown in FIGS. 4A and 4B. a pair of electrodes 104, 106 extend from sensor body 102 and have a space 108 therebetween. Process liquid 108 flows through or is present within space 108 and when an AC voltage is applied to electrodes 104, 106, a contacting-type conductivity measurement is made. In the illustrated example, electrode 104 generally has the form of a band, ribbon, or strip loop that extends around inner electrode 106, which is generally shown as a rectangular block. In some embodiments, one or both of electrodes 104, 106 may be replaceable. The shape of electrode 104 facilitates the generation of a corrosion diagnostic and the resistance of electrode 104 may be measured by the analyzer. Conductor resistance is a property of a conductor at a specific temperature, and it is defined as the amount of opposition there is to the flow of electric current through a conducting medium. The resistance of a conductor depends on the cross-sectional area of the conductor, the length of the conductor, and its resistivity. Electrode 104 does not change its resistivity or length. Therefore, a change in resistance of electrode 104 will indicate a change in cross-sectional area of electrode 104, thus indicating corrosion. Further, while embodiments described herein show only one of electrodes 104, 106 having the band or ribbon shape, it is expressly contemplated that both electrodes could be shaped as a band, ribbon or strip loop such that the resistance of both electrodes could be measured.

FIG. 5 is a circuit diagram illustrating for measurement of corrosion of an electrode of a contacting-type conductivity sensor in accordance with an embodiment of the present invention. For the sake of illustration, inner electrode 106 is not shown in FIG. 5. Contacting-type conductivity sensor 100 includes sensor body 102 that is coupled to an analyzer instrument 120 via a plurality of conductors 122, 124, 126, 128, and 130. FIG. 5 shows strip-loop shaped outer electrode 104 having a first end 132 proximate sensor body 102 and a second end 134 proximate sensor body 102. As shown, conductor 122 is coupled to electrode 104 proximate end 132, while conductor 126 is coupled to electrode 104 proximal end 134. This configuration allows analyzer instrument 120 to measure the resistance of electrode 104.

As set forth above, a change in the resistance of electrode 104 over time is indicative of corrosion. The resistance of electrode 104 is generally low and the differences in resistance due to corrosion (at least at first) may be very slight. Thus, in some examples, embodiments described herein include a reference element 136 that is preferably substantially the same length, width and composition of electrode 104. However, reference element 136 is disposed within sensor body 102 and is not exposed to process fluid. As shown, reference element 136 has a first end 138 that is coupled to conductor 128 and a second end 140 that is coupled to conductor 126. Analyzer instrument 120 includes a voltage source 142, that is shown as an AC voltage source. While AC voltage source 142 may be the same AC voltage source used for obtaining conductivity measurements, it is expressly contemplated that voltage source 142 may be different than that used for conductivity measurement and need not even be an AC voltage source. Analyzer instrument 120 includes a potentiometer of voltage measurement device 144 that is coupled to conductor 128 via resistor 146 and is coupled to conductor 124 via resistor 148. Additionally, voltage measurement device is coupled to conductor 126. In some examples resistors 146, 148 have the same resistance such that the circuit is completely balanced at an initial condition with no corrosion. However, one or both of resistors 146, 148 may be a variable resistor to allow an end user to adjust the circuit to achieve an initial balance when the sensor is first installed.

As corrosion begins to occur, the metal electrode 104 (illustrated as “Exposed Element”) will become smaller. As electrode 104 gets smaller due to corrosion, the resistance of the electrode will increase. As the resistance of electrode 104 increases, the resistance of reference electrode 136 will remain the same. Thus, the circuit will become imbalanced and a voltage will be detectable by voltage measurement device 144. Analyzer instrument 120 uses the detected voltage from voltage measurement device to provide a corrosion diagnostic that may be live, real-time, or substantially real-time. Additionally, even in embodiments where the corrosion diagnostic is not provided as a continuous real-time value, it may still easily be provided on a relatively high frequency (e.g., every 10 minutes, every hour, every day) rather than the 3 or 4 months specified for corrosion coupons. Additionally, since the corrosion diagnostic is provided so frequently, it can also be used to essentially monitor asset integrity.

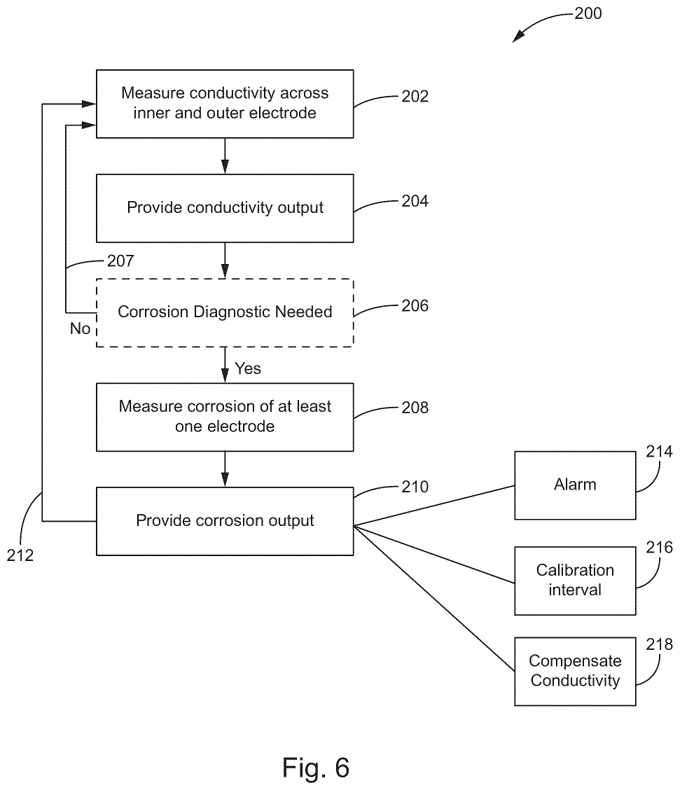

FIG. 6 is a flow diagram of a method of measuring corrosion of a contacting-type conductivity sensor in accordance with an embodiment of the present invention. Method 200 begins at block 202 where an analyzer instrument measures conductivity across a pair of electrodes of a contacting-type conductivity sensor that is exposed to a process fluid, such as cooling water. In some examples, the pair of electrodes may include a strip-loop shaped electrode disposed about an inner electrode. However, embodiments encompass any suitable physical arrangement where at least one of the electrodes has a configuration that allows its resistance to be measured, while still providing suitable surface area for its function as a contacting-type conductivity sensor electrode. Next, at block 204, the analyzer instrument provides a conductivity output based on the measured conductivity. Method 200 then proceeds to optional block 206, where it is determined whether a corrosion diagnostic is needed. Block 206 is optional since embodiments can be practiced where the corrosion diagnostic is performed with every conductivity measurement. However, since corrosion generally occurs slower than conductivity of the process fluid changes, the corrosion diagnostic can be performed periodically (e.g., every minute, every 5 conductivity measurements, once a day). Block 206 is generally performed by a controller within analyzer instrument 120. The controller may be a microprocessor which may include or be coupled to a real-time clock in order to support the programmatic determination provided by block 206. If a corrosion diagnostic is not needed, then method 200 repeats by returning to block 202 as indicated by line 207.

If, at block 206, it is determined that a corrosion diagnostic is needed, or in embodiments where block 206 is not provided, method 200 proceeds to block 208 where corrosion of at least one electrode is measured. As set forth above, this corrosion measurement is done by measuring the resistance of at least one electrode of the contacting-type conductivity sensor. In embodiments where the resistance of both electrodes is measured, the measurements may be combined to provide an average corrosion. Additionally, or alternatively, the highest resistance of the two measurements may be used such that the reported corrosion is that of the worst-corroded electrode. Next, at block 210, the result of the corrosion diagnostic is provided. This output can be in the form of an alert 214 that is generated when the corrosion reaches a pre-selected threshold. The alert can be a local audio and/or visual alarm. Additionally, or alternatively, the alert can be a message (e.g., SMS, email, process communication, et cetera) generated to a responsible party or maintenance technician indicating the current level of corrosion and/or a projected time when the sensor will require recalibration or replacement.

As shown in FIG. 6, the corrosion output may be an adjustment to a calibration interval 216 of the sensor. Thus, as the sensor begins to become corroded, it may be calibrated more frequently. FIG. 6 also shows that the corrosion diagnostic output may be simply a conductivity output that is compensated for the corrosion determined during the corrosion diagnostic. As set forth above, as the electrode corrodes, the cell constant will change. The controller, or other suitable logic or components of the analyzer, may include a lookup table that relates measured corrosion to a change in cell constant. Thus, analyzer 120 may use the determined corrosion value to consult the lookup table to obtain a corresponding change in cell constant and apply the changed cell constant to the conductivity measurement output. Additionally, in situations where the conductivity measurement is compensated for corrosion, analyzer 120 may provide an indication of such.

Once the output of the corrosion diagnostic has been provided, method 200 repeats by control returning to block 202 via line 212.

Although the present invention has been described with reference to preferred embodiments, workers skilled in the art will recognize that changes may be made in form and detail without departing from the spirit and scope of the invention.

What is claimed is:

1. A contacting-type conductivity sensor comprising:
a first electrode configured to contact a liquid;
a second electrode configured to contact the liquid, the second electrode having a first end and a second end;
a first conductor coupled to the first electrode;
a second conductor coupled to the first end of the second electrode;
a third conductor coupled to the second end of the second electrode; and
wherein the contacting-type conductivity sensor is configured to provide a conductivity measurement of liquid using the first and second conductor, and is configured to provide a corrosion diagnostic using the second conductor and the third conductor.

2. The contacting-type conductivity sensor of claim 1, wherein the second electrode is a strip-loop shaped electrode disposed about the first electrode.

3. The contacting-type conductivity sensor of claim 2, wherein the first electrode is rectangular.

4. The contacting-type conductivity sensor of claim 3, wherein the conductivity measurement is of liquid disposed between the first and second electrodes.

5. The contacting-type conductivity sensor of claim 1, and further including a reference element having a first end and a second end, wherein the second end of the reference element is coupled to the third conductor.

6. The contacting-type conductivity sensor of claim 5, and further comprising a fourth conductor coupled to the first end of the reference element.

7. The contacting-type conductivity sensor of claim 6, wherein the reference element is configured to be the same length as the second electrode.

8. The contacting-type conductivity sensor of claim 7, wherein the reference element is disposed within a body of the contacting-type conductivity sensor and is isolated from the liquid.

9. The contacting-type conductivity sensor of claim 1, wherein each of the first and second electrodes is shaped as a ribbon.

10. The contacting-type conductivity sensor of claim 1, wherein each of the first and second electrodes is shaped as a ribbon.

11. The contacting-type conductivity sensor of claim 1, wherein each of the first and second electrodes is shaped as a strip loop.

12. A conductivity measurement system comprising:
a conductivity analyzer having a voltage source and a voltage measurement device; and
a contacting-type conductivity sensor including:
a first electrode configured to contact a liquid;
a second electrode configured to contact the liquid, the second electrode having a first end and a second end;
a first conductor coupling the first electrode to the conductivity analyzer;
a second conductor coupling the conductivity analyzer to the first end of the second electrode;
a third conductor coupling the conductivity analyzer to the second end of the second electrode; and
wherein the conductivity analyzer is configured to generate a conductivity output based on a conductivity measurement of the contacting-type conductivity sensor using the first conductor and one of the second and third conductors, the conductivity analyzer being further configured to generate a corrosion diagnostic output using the second and third conductors.

13. The conductivity measurement system of claim 12, wherein the contacting-type conductivity sensor includes a reference element having a first end and a second end, wherein the second end of the reference element is coupled to the third conductor.

14. The conductivity measurement system of claim 13, and further comprising a fourth conductor coupling the first end of the reference element to the conductivity analyzer.

15. The conductivity measurement system of claim 14, wherein the conductivity analyzer includes a voltage measurement device operably coupled to the second electrode and the reference element, the voltage measurement device being configured to provide an indication of resistance change of the second electrode, which resistance change is indicative of corrosion of the second electrode.

16. The contacting-type conductivity sensor of claim 15, wherein the reference element is configured to be the same length as the second electrode.

17. The contacting-type conductivity sensor of claim 16, wherein the reference element is disposed within a body of the contacting-type conductivity sensor and is isolated from the liquid.

18. The conductivity measurement system of claim 12, wherein the corrosion diagnostic output is an alert.

19. The conductivity measurement system of claim 12, wherein the corrosion diagnostic is an adjustment to a calibration interval.

20. The conductivity measurement system of claim 12, wherein the corrosion diagnostic output is a compensated conductivity output.

21. The conductivity measurement system of claim 20, wherein the compensated conductivity output includes an indication that the output is compensated for corrosion.

22. The conductivity measurement system of claim 12, wherein the corrosion diagnostic output is provided in real-time.

23. A method of operating a contacting-type conductivity sensor; the method comprising;
measuring conductivity across first and second conductivity electrodes, which electrodes are in contact with a process liquid;
generating a conductivity output based on the measured conductivity;
measuring a resistance of at least one of the first and second electrodes; and
providing a corrosion diagnostic output based on the measured resistance.
